(19) United States
(12) Patent Application Publication
(10) Pub. No.: US 2024/0203965 A1
(43) Pub. Date: Jun. 20, 2024

(54) METHOD FOR BONDING AND INTERCONNECTING MICRO-ELECTRONIC COMPONENTS

(71) Applicant: IMEC VZW, Leuven (BE)

(72) Inventors: Jaber Derakhshandeh, Tienen (BE); Eric Beyne, Heverlee (BE)

(21) Appl. No.: 18/538,422

(22) Filed: Dec. 13, 2023

(30) Foreign Application Priority Data
Dec. 14, 2022 (EP) 22213368.8

(51) Int. Cl. H01L 25/16; H01L 21/768; H01L 23/00; H01L 25/00

(52) U.S. Cl. CPC H01L 25/162; H01L 21/7684; H01L 24/80; H01L 25/50; H01L 2224/80895; H01L 2224/80896

(57) ABSTRACT

A method for bonding and interconnecting micro-electronic components is provided. In one aspect, two substrates are bonded to form a 3D assembly of micro-electronic components. Both substrates include first cavities open to the respective bonding surfaces, and at least one substrate includes a second cavity that is larger than the first cavities in terms of its in-plane dimensions, and possibly also in terms of its depth. An electrically conductive layer is produced on each substrate. The layer is patterned in the second cavity, and a micro-electronic device is fabricated in the second cavity. The bonding surfaces are planarized, removing the conformal layer from the bonding surfaces, and the substrates are bonded to form the assembly, where the first cavities of both substrates are brought into mutual contact to form an electrical connection. Device in the large cavities may be contacted through TSV connections or back end of line interconnect levels.

### CROSS-REFERENCE TO RELATED APPLICATIONS

This application claims foreign priority to European Application EP 22213368.8, filed Dec. 14, 2022, the content of which is incorporated by reference herein in its entirety.

### BACKGROUND

### Technological Field

The disclosed technology relates to the bonding and interconnecting of micro-electronic components, such as integrated circuit chips, interposer substrates and printed circuit boards.

### Description of the Related Technology

3D integration of microchips involves the bonding and interconnecting of multiple stacked chips, and/or the bonding and interconnecting of a chip to a larger carrier component such as an interposer or a printed circuit board (PCB). For microchips which include larger devices such as MEMS devices or superconducting quantum qubits, these larger devices are often produced on separate chips, which are subsequently bonded to a carrier such as an interposer or PCB by microbump bonding. In cases where the spacing between the device and the carrier is of crucial importance, this approach is often unable to realize the required spacing because of the inadequate control of the bump thickness. Another problem is that the interconnect density attainable with microbump connections is limited.

### SUMMARY OF CERTAIN INVENTIVE ASPECTS

One objective of some aspects of the disclosed technology is to provide a solution to the problems highlighted above. In some embodiments, this objective is achieved by a method and by an assembly of micro-electronic components as described herein. According to embodiments of the disclosed technology, a first and a second substrate are bonded to each other to form a 3D assembly of micro-electronic components. Both substrates include a plurality of first cavities open to the respective bonding surfaces. At least one substrate includes a second cavity that is much larger than the first cavities in terms of its in-plane dimensions, and possibly also in terms of its depth. Prior to bonding, an electrically conductive layer is produced conformally on each substrate. The layer is patterned in the large cavity or cavities, and in the large cavity or cavities a micro-electronic device or a portion thereof is fabricated. Thereafter, the bonding surfaces are planarized, removing the conformal layer from the bonding surfaces, after which the substrates are bonded to form the assembly, wherein the first cavities of both substrates are brought into mutual contact to form an electrical connection. In some embodiments, the first cavities may be filled with a contact material such as copper or solder prior to the planarization step. Any device in the large cavities may be contacted through suitable connections, such as though substrate via (TSV) connections or back end of line interconnect levels. The formation of the devices or device parts in pre-formed cavities can enable an improved control of a number of device properties, such as the spacing between two capacitor plates. In addition, the interconnect through direct bonding of the bonding surfaces can enable a higher interconnect density compared to microbump-based interconnects.

One aspect of the disclosed technology relates to a method of producing a stacked assembly of micro-electronic components, the method including the steps of:
providing a first and a second substrate, each substrate having a planar bonding surface, wherein:
   the first substrate and the second substrate both include a group of first cavities open to the respective bonding surfaces,
   the groups of first cavities are arranged in mutually matching patterns on the first and the second substrate,
   at least one of the substrates includes at least one second cavity open to the bonding surface of the substrate, wherein the second cavity has larger in-plane dimensions than the in-plane dimensions of the first cavities,
   at least one of the substrates includes electrical conductors embedded in the substrate and available for contacting the conductors at a bottom portion of the first cavities and/or the second cavity,
producing a first and a second layer formed of a first electrically conductive material on the respective bonding surfaces, the layers conformally covering the bonding surfaces and the sidewalls and bottom surfaces of the first cavities and of the second cavity,
patterning the layer formed of the first conductive material in the second cavity and producing a micro-electronic device or a part thereof in the second cavity, wherein the device or part does not extend above the bonding surface of the substrate including the second cavity,
by a planarization technique, removing the layers formed of the first electrically conductive material from the bonding surfaces while keeping the layers at least on the bottom and sidewalls of the first cavities,
bonding and interconnecting the substrates, to thereby obtain the stacked assembly of components, wherein at least the sidewalls of the first cavities of the first substrate overlap corresponding sidewalls of the first cavities of the second substrate so that an electrical connection is established between the respective sidewalls, and wherein the device or device part in the second cavity is electrically connected to one or more other components of the stack.

In some embodiments, the method further includes the following steps applied to the two substrates:
prior to applying the planarization technique, depositing a second electrically conductive material in the first cavities and on the bonding surface in between the first cavities,
by applying the planarization technique, removing both the second and first conductive materials from the bonding surface, before performing the bonding step.

In some embodiments, on at least one of the substrates, the second cavity and a plurality of the first cavities are together forming a common cavity, the plurality of the first cavities branching out from one or more sidewalls of the second cavity, wherein the layer of the first conductive material is maintained on the one or more sidewalls of the second cavity so that the layer forms an electrical connection between the plurality of the first cavities and the second cavity.

In some embodiments, the electrical connection between the matching first cavities of the two substrates is established only by the layers of the first conductive material on the sidewalls and the bottom of the first cavities.

In some embodiments, the first cavities have an elongate shape, wherein the first cavities of the first substrate overlap the first cavities of the second substrate in a crosswise fashion.

In some embodiments, at least one of the substrates includes a plurality of conductors embedded in the substrate and arranged so that a number of the conductors are available for contacting at the bottom of the first cavities and/or at the bottom of the at least one second cavity.

In some embodiments, at least some of the number of conductors are through substrate via (TSV) connections.

In some embodiments, at least some of the number of conductors are interconnect vias that are part of a back end of line type interconnect structure.

In some embodiments, the depth of the second cavity is considerably larger than the depth of the first cavities.

In some embodiments, the depth of the second cavity is the same as the depth of the first cavities.

In some embodiments, the devices or parts thereof are superconducting qubits or parts thereof.

In some embodiments, the first substrate includes a number of the second cavities, each of the number of second cavities including multiple elements of a superconducting qubit including one plate of a capacitor, wherein the second substrate includes an equal number of the second cavities, each including another capacitor plate that is capacitively coupled to the plates in the first substrate after the bonding step.

Another aspect of the disclosed technology relates to a stacked assembly of micro-electronic components, in which at least two of the components are bonded along a bonding interface. The stacked assembly may include matching pluralities of interconnected first cavities open to the bonding interface. The first cavities of the two components may be interconnected at least by layers of a first electrically conductive material lining the sidewalls and bottom of the first cavities, at least one component may further include a second cavity open to the bonding interface that has in-plane dimensions that are larger than the in-plane dimensions of the first cavities, and the second cavity may include a micro-electronic device or a part thereof that is electrically connected to one or more other components of the stacked assembly.

In some embodiments, the devices or parts thereof are superconducting qubits or parts thereof.

### BRIEF DESCRIPTION OF THE DRAWINGS

FIGS. 1A, 1B and 1C illustrate an assembly of components produced according to an embodiment of the disclosed technology.

FIGS. 2A to 2H illustrate example method steps for producing the assembly shown in FIGS. 1A and 1B.

FIGS. 3A to 3D illustrate one method of producing a substrate including TSVs of different depths and one or more large cavities.

FIGS. 4A to 4C illustrate an alternative embodiment in which the smaller cavities are formed in a dielectric bonding layer.

FIG. 5 illustrates a number of alternatives for some features of the disclosed technology.

FIG. 6 illustrates an embodiment in which smaller cavities are branching out from a larger cavity in one of the substrates that are to be bonded.

FIGS. 7A to 7E illustrate example steps for producing the assembly shown in FIG. 6.

FIG. 8 illustrates an integrated circuit chip that is to be processed and bonded to another substrate, according to an embodiment of the disclosed technology.

FIGS. 9A to 9E illustrate steps of an example method which may be applied to the integrated circuit chip shown in FIG. 8.

FIG. 10 illustrates an assembly of components where the large cavities are completely filled.

### DETAILED DESCRIPTION OF CERTAIN ILLUSTRATIVE EMBODIMENTS

In the following detailed description, all references to specific materials and dimensions are included by way of example only, and none of these citations are to be construed as limitations of the protection scope.

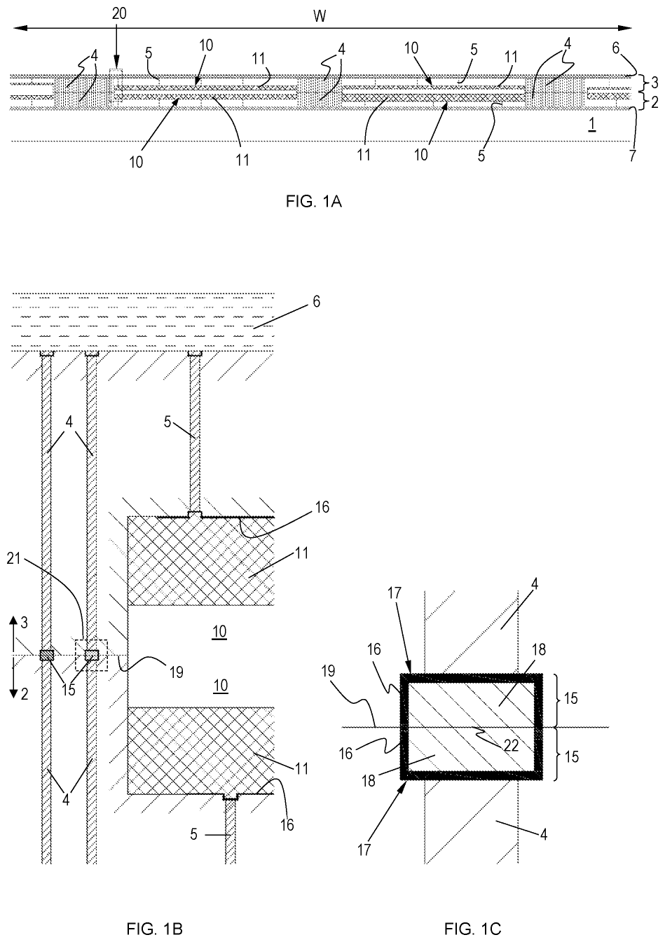

FIG. 1A shows a small section of an assembly of micro-electronic components, two of which have been assembled according to an embodiment of the disclosed technology. The assembly includes a PCB board 1, an interposer 2 mounted on the PCB board, and a microchip 3 mounted on the interposer. Embodiments of the disclosed technology are relevant for the bonding of the chip 3 to the interposer 2. The image shows a section of width W of the stacked components, W being in the order of less than 1 mm, that is, all three components extend for considerable lengths on either side of the illustrated section, the chip 3 being the smallest of the three. In the example shown, the microchip 3 and the interposer 2 are formed of silicon and are bonded together by direct silicon-on-silicon bonding of the bonding surfaces at the front sides of these two components. Other examples can be suitably implemented. So called “through substrate via” connections 4 and 5, hereafter abbreviated as TSV connections or TSVs, connect the front side of the chip 3 and of the interposer 2 to the back sides of these components. On the back side of the chip 3, a redistribution layer 6 is provided for interconnecting selected TSVs in the horizontal plane. The back side of the interposer 2 is bonded to a redistribution layer 7 on the front side of the PCB 1.

It is further shown in FIG. 1A that both the chip 3 and the interposer 2 are provided with cavities 10 that are open to the bonding surfaces. These cavities 10 have in-plane dimensions that are large in comparison with the diameter of the TSVs 4. Inside these large cavities 10, micro-electronic devices or parts thereof have been fabricated according to methods of the disclosed technology, as will be described hereafter in more detail. The devices or parts thereof have been represented symbolically as hatched areas 11, but they can have multiple practical realizations and forms, not necessarily filling the full surface area of the cavities 10. The cavities 10 may, for example, include MEMS (micro-electromechanical system) devices or optical devices or parts thereof, or other micro-electronic devices or device portions. One particular application may be the realization of a quantum processor wherein superconducting qubits or parts thereof are fabricated in the large cavities 10, leaving a specific desired gap between qubits or qubit parts fabricated in two mutually facing cavities 10 for improved qubit fidelity performance.

Still with reference to FIG. 1A, it is shown that dense arrays of TSVs 4 are located in the areas between the large cavities 10. These densely packed TSVs 4 form connections between the front and back sides of the chip 3 and of the interposer 2. A smaller number of TSVs 5 connect the bottom area of the large cavities 10 to the back side of the chip 3 and the interposer 2. On the basis of the enlarged images shown in FIGS. 1B and 1C, these different TSVs and their interconnection will now be described in more detail.

In the enlarged view of the rectangle 20, illustrated in FIG. 1B, and in the further enlargement of the interconnection 21 shown in FIG. 1C, it is shown that the densely packed TSVs 4 of the chip 3 and the interposer 2 are in physical and electrical contact with contact pads 15 on the respective bonding sides of these two substrates (chip and interposer). Each of these contact pads 15 includes a thin electrically conductive layer 16 on the bottom and sidewalls of small cavities 17, and an electrically conductive volume 18 that further fills the cavities 17. The contact pads 15 may have a circular cross-section having a diameter in the order of few micrometer down to submicron (that is, <1 μm, for example about 0.5 μm), while the TSVs 4 may also have a circular cross-section whose diameter is smaller than the contact pad diameter. The TSV diameter may therefore also be in the order of few μm or smaller. The contact pads 15 and/or the TSVs 4 could also have a non-circular cross-section, for example an elongate rectangle-like cross-section, as will be described further below.

The large cavities 10 may have in-plane dimensions (for example, the length of one side in the case of a square cavity or the diagonal in the case of a rectangular shape) in the order of tens or hundreds of micrometers depending on the application. The depth of these large cavities 10 may be essentially constant across the surface area of the cavities and, again depending on the application, the value of this depth may vary within a broad range, between a few hundred nanometers, being equal to or in the same order of magnitude as the depth of the small cavities 17, up to tens of micrometers. The latter (that is, deeper) cavities 10 may be required for specific larger devices or device parts, such as MEMS or optical devices. In the example shown, the depth of the large cavities 10 is about 10 μm and these cavities may have a square shape with a side dimension in the order of about 100 μm, which are dimensions that can be suitable for an application in the field of superconducting quantum computing (hereafter abbreviated as superconducting QC).

The volumes 18 may consist of a low resistive metal such as a solder or copper or any superconducting (hereafter abbreviated as SC) metals (for example, Al, TiN, Nb) for QC applications. Matching 2-dimensional arrays of contact pads 15 are provided on the chip 3 and on the interposer 2 and these matching arrays are brought into mutual contact to form an electrical connection through the bonding process, which may be a hybrid bonding process, for example, a combination of direct Si-to-Si bonding and metal to metal bonding, to thereby form the Si—Si interface 19 between the two substrates and multiple metal-to-metal electrical interconnects 21. The dividing line 22 between the volumes 18 may not be physically present, depending on the material used for these volumes. When the material is a solder, for example, the two volumes will melt and eventually form a continuous volume of solder or intermetallic material.

The thin conductive layer 16 is also shown on a portion of the bottom area of the large cavities 10 in FIG. 1B. The use of the same reference numeral 16 illustrates the fact that the layer 16 on the bottom of the large cavities 10 originates from the same deposition as the layers 16 that are lining the small cavities 17, and that (in the case illustrated) this layer 16 is patterned inside the area of the large cavity 10, in accordance with the design requirements of whichever device or device part 11 that is to be fabricated in the cavity 10. These features of embodiments of the disclosed technology will now be described in more detail.

A method of producing an assembly of two components like the illustrated chip 3 and interposer 2, will now be described, in accordance with an embodiment of the disclosed technology, for the case of a direct silicon-to-silicon bond, which is for example suitable for the application of the disclosed technology in the field of superconducting QC. The method may include a bonding step as well as a number of method steps applied prior to bonding. These preparatory method steps may be applied at wafer level, for example, on a larger process wafer that is to be divided into smaller chips and/or interposers at a later stage. The bonding step may be applied at wafer level or at die-level, for example, it may be a wafer-to-wafer bonding step, a die-to-wafer bonding step or a die-to-die bonding step, depending on the application.

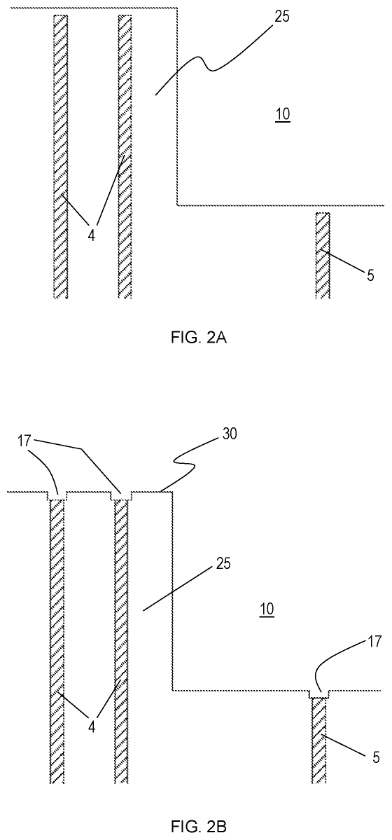

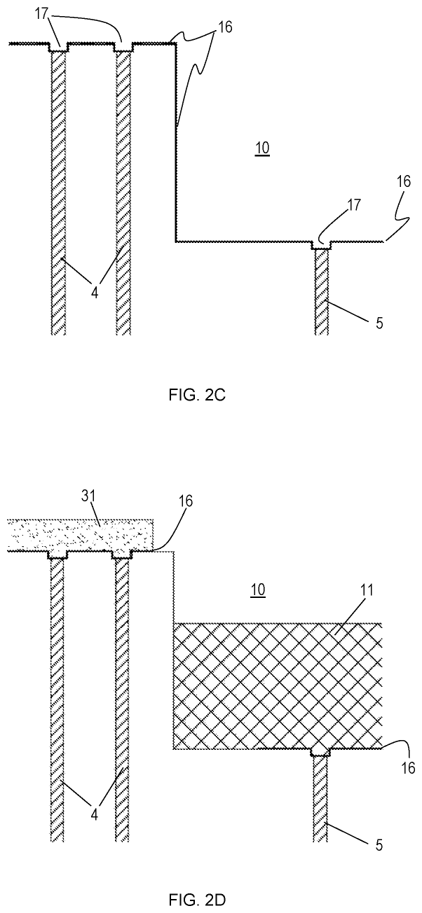

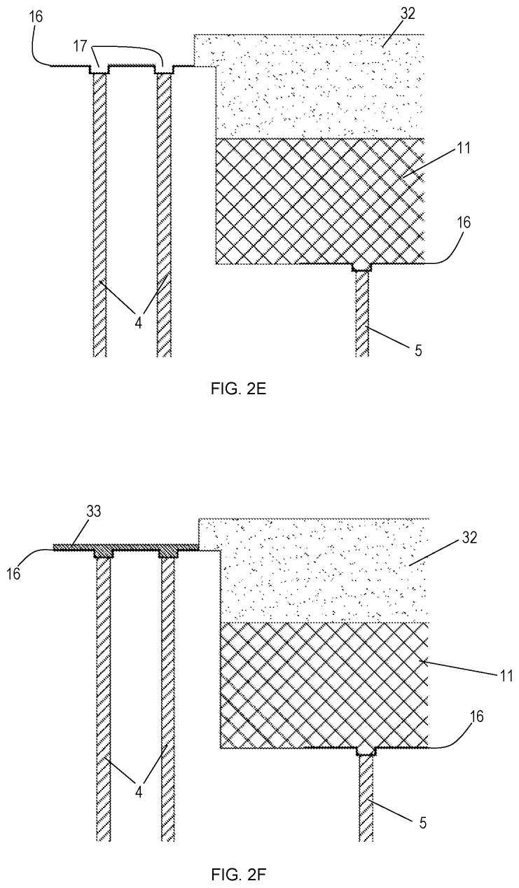

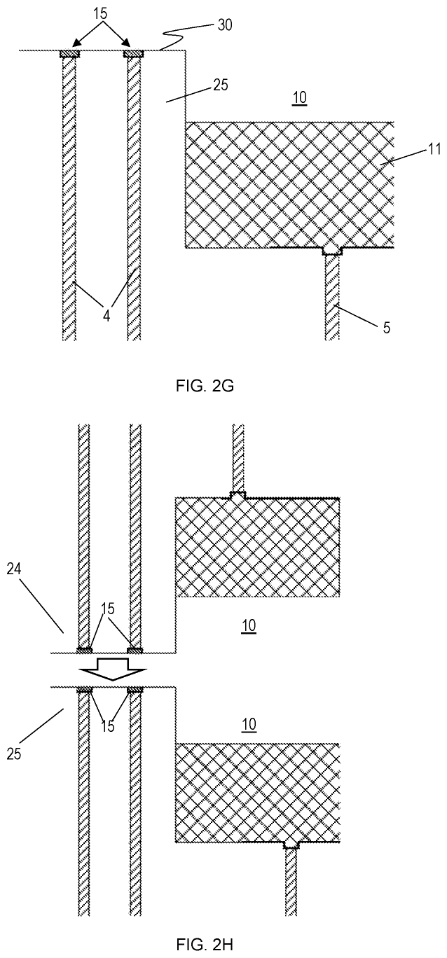

FIG. 2A shows a detail of the interposer substrate 25, that is, the substrate from which the actual interposer 2 will be obtained by dicing the substrate into smaller portions. This substrate 25 may be a silicon wafer onto which multiple interposers are to be processed. The substrate 25 is provided with the TSVs 4, 5 and with a large cavity 10 as referred to above, that is, the TSVs 4 are part of a dense array of TSVs passing through to the opposite side of the substrate 25, while TSVs 5 are located under the cavity 10. In the specific case shown, the TSVs 4 and 5 terminate at a short distance of, for example, 100 nm from the upper surface of the substrate and from the bottom surface of the cavity 10, respectively. This is specific to the case of Si-to-Si bonding and it is not a limitation of the disclosed technology. The way in which the substrate 25 including the TSVs 4, 5 as shown in FIG. 2A may be obtained will, however, be described first, as it is relevant also to other embodiments.

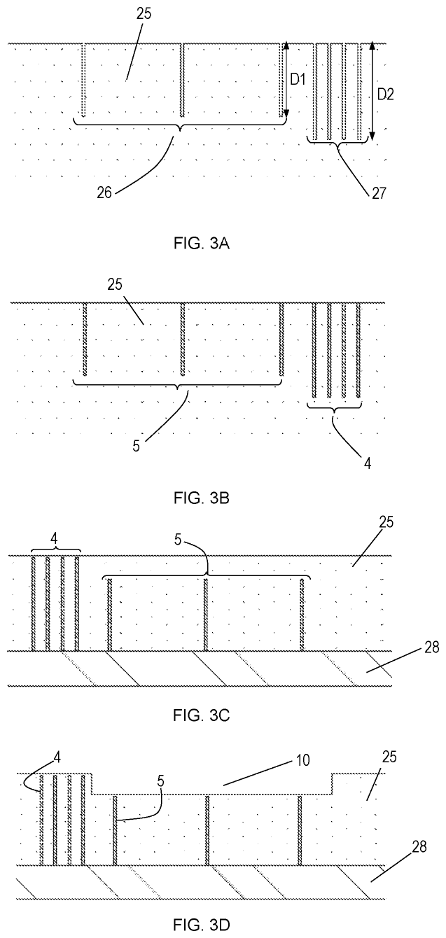

Reference is therefore first made to FIGS. 3A to 3C. A standard monocrystalline silicon process wafer 25 is used as the starting point, according to an embodiment of the disclosed technology. Such a wafer may have a thickness of several hundreds of micrometers and a diameter of 200 mm or 300 mm or others. A first and a second set of TSV openings 26 and 27 are produced by two consecutive lithography and etch sequences. The openings may have a diameter in the order of 300-400 nm for example, and are etched down to two different depths D1 and D2, with a difference of about 10 μm. The depth of the openings from the surface of the wafer may be in the order of a hundred micron, so for example D1 may be about 100 μm and D2 may be about 110 μm. Litho/etch processes which can be suitably implemented to produce such openings in silicon are not described here in detail. These openings 26 and 27 are subsequently filled with an electrically conductive material, for example copper or any SC metal (for QC applications) as illustrated in FIG. 3B, possibly after first lining the sidewalls of the openings with a dielectric liner and after the formation of a seed layer and possibly a barrier layer (not shown). Such layers as well as deposition techniques for filling the openings can be implemented using many suitable techniques.

The upper surface of the silicon wafer 25 is planarized to remove the electrically conductive material deposited thereon, and to expose the top faces of the TSVs 4 and 5, as illustrated in FIG. 3B. With reference to FIG. 3C, the wafer is then flipped and temporarily bonded to a carrier substrate 28 by a suitable bonding layer (not shown), and the wafer is thereafter thinned from the back side, by grinding and planarization techniques such as CMP (chemical mechanical polishing). Planarization is stopped before reaching the deepest set of TSVs 4, for example stopping when about 100 nm of silicon is left above the end faces of the TSVs 4. Then, as illustrated in FIG. 3D, the large cavity 10 is formed by lithography and etching, while covering the areas of the first set of TSVs 4 by a suitable mask (not shown). Etching of the large cavity 10 is stopped before exposing the TSVs 5 of the second set, also leaving for example about 100 nm of Si above the end faces of those TSVs 5. These process steps thus yield the structure as shown in FIG. 2A. According to other embodiments described below, the thinning and etching steps are performed such that the TSVs 4 and 5 protrude slightly (for example by about 100 nm) through the surface of the silicon wafer 25, which is then followed by the deposition of an oxide layer to embed the protruding ends of the TSVs therein. However, for the fabrication of superconducting qubits, no oxide formation may be allowed as this may have a detrimental effect on the coherence time of the qubits.

Returning then to FIG. 2A and to the subsequent FIG. 2B, a plurality of small cavities 17 is formed in alignment with the positions of the TSVs 4 and 5, exposing the TSVs 4 and 5 at the bottom of these small cavities 17. The small cavities are open to the bonding surface 30, that is, the upper rim of the sidewalls of these cavities 17 is at the same level as the bonding surface 30. The term “small” refers to the in-plane dimensions of these cavities 17 which are small compared to the in-plane dimensions of the large cavities 10. As stated above, the small cavities 17 may be circular in shape, having a diameter of about 500 nm for example, whereas the larger cavities 10 may have in-plane dimensions of up to several hundreds of micrometers, depending on the application. The formation of the small cavities 17 can be done by lithography and etch techniques. Small cavities 17 are also formed inside the larger cavity 10, in alignment with the location of the TSVs 5. The initial large cavity 10 including the small cavities 17 at the bottom thereof is to be regarded as a single “second cavity.” The substrate onto which the microchip 3 is to be processed is prepared in the same way, that is, having an array of small cavities 17 open to the bonding surface and a number of larger cavities 10. For preparing the specific assembly shown in FIGS. 1A and 1B, the following steps may be applied to both the interposer substrate and the chip substrate.

With reference to FIG. 2C, a thin electrically conductive layer 16 is deposited conformally, that is, following the topography of the small and large cavities 17 and 10. This layer 16 may be thin, for example a few nanometers thick. When the method is applied in the field of superconducting QC, this layer 16 may be any metal having superconducting characteristics, such as Al, Ta, TaN, Ti, TiN, TiW, Ru, Zr, ZrN, Mo, In, Nb, NbTi, NbN, NbTiN, Nb₃Al or others. The layer 16 may be applied by PVD (physical vapor deposition) or ALD (atomic layer deposition) or CVD (chemical vapor deposition) or any other methods.

Following this and with reference to FIG. 2D, a mask layer 31 is applied and patterned by standard lithography. This may be a photoresist layer, for example. The patterning is such that the mask layer 31 covers the array of small cavities 17, while exposing the larger cavities 10. In the larger cavities 10, a number of processing steps are then performed, the result of which is also shown in FIG. 2D, starting with the patterning of the thin conductive layer 16. In the case shown, this layer is removed from the sidewalls of the large cavity 10 and on the bottom of this large cavity, the layer is patterned in accordance with a given device layout. Then the device itself, or a part thereof, either one symbolized by the hatched area 11, is produced in the cavity 10, in accordance with any suitable production process for the device in question. For example, in the case of superconducting QC, a qubit or a portion thereof may be processed in one of the large cavities 10 of the chip substrate. One superconducting qubit design includes a pair of Josephson junctions coupled to a capacitor and a resonator. The Josephson junctions and one plate of the capacitor may, for example, be formed in a large cavity 10 of the chip substrate, while the other plate of the capacitor is formed in a matching large cavity of the interposer substrate.

In applications of the disclosed technology, the devices or parts thereof that are formed in the large cavities 10 do not extend above the bonding surface 30 of the substrate wherein such large cavities 10 are formed.

Referring now to FIG. 2E, the next steps according to the particular embodiment illustrated in the drawings include the removal of the mask layer 31, and the formation of a second mask layer 32, now covering the device or device part 11 that has been fabricated in the large cavity 10, while exposing the array of small cavities 17.

A metal layer 33 is then deposited, for example by electrodeposition, using the thin layer 16 as a seed layer, so that the metal is formed only on the exposed areas, as illustrated in FIG. 2F. In the case of superconducting QC, layer 33 may be a solder material, for example a layer of indium. Thereafter, the second mask 32 is stripped and the substrate is subjected to a planarization step, removing the metal 33 as well as the thin conductive layer 16 from the bonding surface 30, as shown in FIG. 2G, thereby creating an array of bonding pads 15 which are coplanar with the bonding surface 30.

This ends the preparation of the hybrid bonding step, which step is then performed by aligning the corresponding pads 15 and bringing the substrates 24 and 25 into mutual contact as illustrated in FIG. 2H, possibly under increased pressure and temperature. Details of the bonding process as such can be implemented for various types of bonding surfaces and metals and are not described here in detail. The result is the assembly as illustrated in FIGS. 1A and 1B. As stated above, bonding may be performed wafer to wafer or die to wafer or die to die. In the particular non-limiting example shown in FIGS. 1A and 1B, the interposer substrate may first be diced to form individual interposers and one interposer 2 is then bonded to the PCB 1. Then the chip substrate is diced to form individual chips, and one or more chips 3 are bonded to the interposer 2. In another example scenario, wafer to wafer bonding (such as substrate 24 to substrate 25) is applied and the obtained stack is diced to form packages of two bonded chips each, which may then be bonded to an interposer or a PCB. The disclosed technology is not limited to these examples and includes any number of combinations.

The devices or device parts 11 produced in the large cavities 10 may be connected to other parts of the assembly through the TSVs 5 and the redistribution layer 6 on the back side of the chip, and/or the redistribution layer 7 on the PCB 1.

The fabrication of the devices or device parts 11 in the cavities 10 can provide an improved control of a number of device properties compared to presently known assembly techniques. For example, in the case of superconducting qubits, the distance between facing capacitor plates can be controlled more accurately by producing the plates in mutually facing large cavities 10, given that the depth of these cavities can be controlled.

Having said this, and as already stated above, the disclosed technology is not limited to QC devices, but encompasses the fabrication of other devices such as MEMS or optical devices in the large cavities 10. For example, a laser may be produced in one cavity 10, and a MEMS micromirror in the opposing cavity 10. Once again, the distance between these cooperating elements can be much better controlled using the approach of the disclosed technology.

An advantage that is common to all applications of the disclosed technology is the fact that the hybrid bonding approach enables a higher density of the contact pads 15 compared to a microbump interconnect approach.

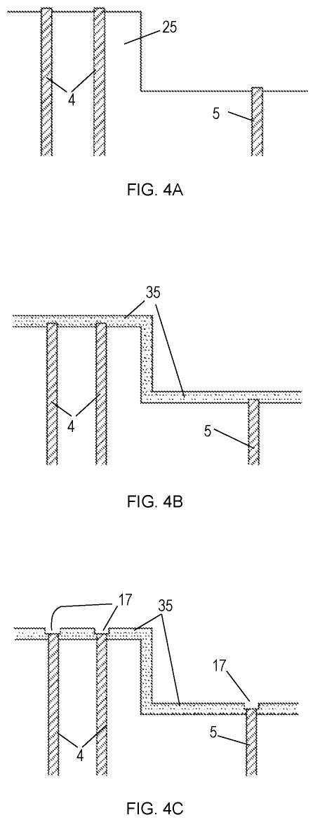

Contrary to QC devices, the fabrication of MEMS or optical devices does allow the use of dielectric bonding layers, such as oxide layers, as well as the use of dielectrics in the large cavities 10. This approach is illustrated in FIGS. 4A to 4C. It is shown that the TSVs 4 and 5 now protrude through the surface of the substrate 25 and that an oxide layer 35, for example formed of SiO₂, is formed on the upper surface of the substrate 25 and on the bottom of the large cavity 10. The small cavities 17 are formed in the oxide layer 35. After this, the steps can be the same as described above. The oxide layer 35 serves as the bonding layer in a dielectric-to-dielectric (for example SiO₂ to SiO₂) direct hybrid bonding process, by which an assembly similar to the one shown in FIGS. 1A and 1B may be obtained.

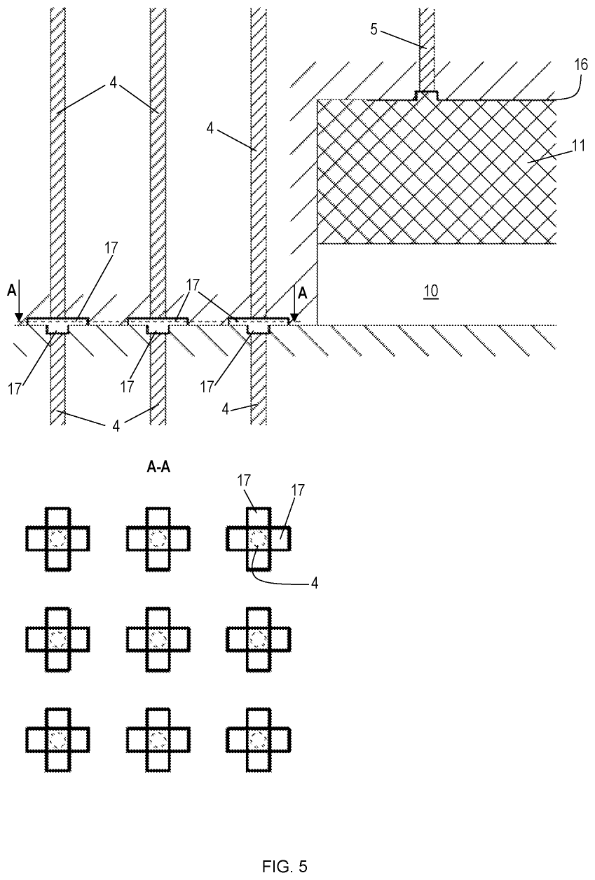

FIG. 5 illustrates a number of possible alternatives for some of the features described so far. The alternatives are shown in the same image, but they can be applied independently from each other. The first alternative regards the shape and relative orientation of the small cavities 17. As shown in FIG. 5, these small cavities 17 may have elongate shapes, represented as rectangles in the image, with the cavities 17 of the two substrates overlapping each other at essentially right angles. The shapes may be rounded at the narrow ends. A second alternative is related to the filling of the small cavities 17. According to embodiments, it is possible to skip the steps illustrated in FIGS. 2E and 2F, that is, the small cavities 17 are not filled with the metal 33, and the CMP step removes only the thin layer 16 from the bonding surface 30. This thin layer 16 alone then establishes the electrical connection between the bonded substrates. This embodiment can be applied in cases where the devices or device parts produced in the large cavities 10 are incompatible with a number of contact metals or solder materials. Although these features (long cavities and no solder/metal fill) can be applied independently from each other, their combination is especially useful as the overlapping elongate shapes ensure that an electrical connection between the cavities 17 can be established also in the case of a limited misalignment. A third alternative illustrated in FIG. 5 is an example embodiment in which the lower substrate does not include a large cavity facing the large cavity 10 on the upper substrate. In fact, the disclosed technology is not limited to the case where both bonded substrates include both large and small cavities. It is sufficient that both substrates include small cavities 17 and at least one substrate includes one or more large cavities 10.

In the embodiment of FIG. 5, the cross-section of the TSVs 4 and 5 need not be circular in shape, but could also be rectangular.

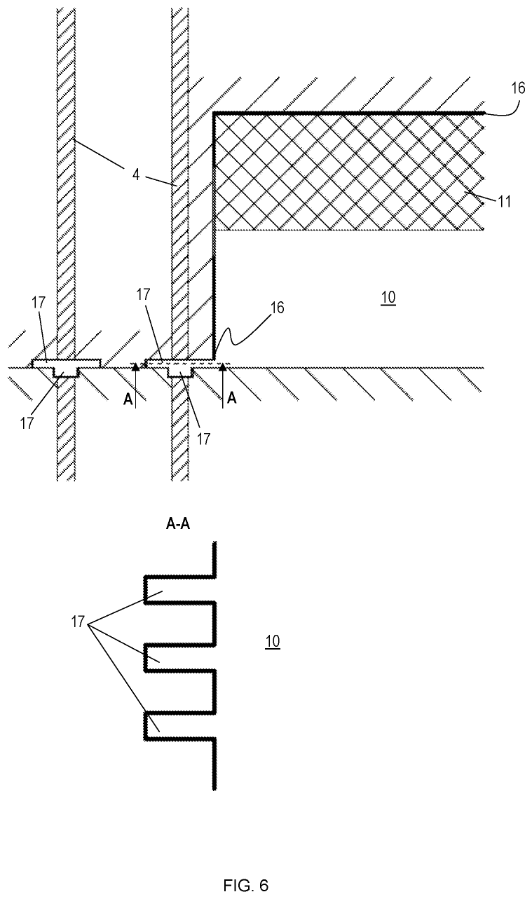

According to an embodiment of the disclosed technology, the thin conductive layer 16 is used to realize an electrical connection between a number of the small cavities 17 and a large cavity 10 directly bordering these small cavities 17 on the same substrate. Such an embodiment is illustrated in FIG. 6. It is shown that the thin conductive layer 16 has now been maintained on the sidewall of the large cavity 10, and that a number of small cavities 17 are directly bordering the large cavity, so that the large cavity 10 and these directly bordering small cavities 17 form one common cavity. In a top view, as illustrated in FIG. 6, it is shown that the small cavities 17 are branching out from the large cavity 10. The thin conductive layer 16 connects the device 11 inside the large cavity 10 to the small cavities 17 branching out from the larger one. This is therefore an alternative way of contacting the device 11.

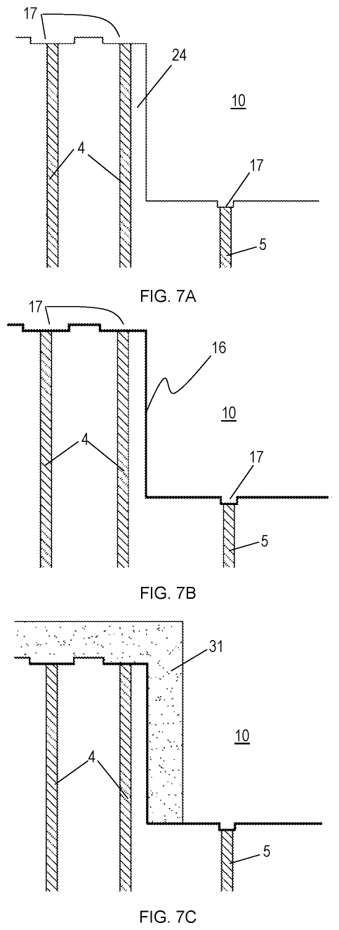

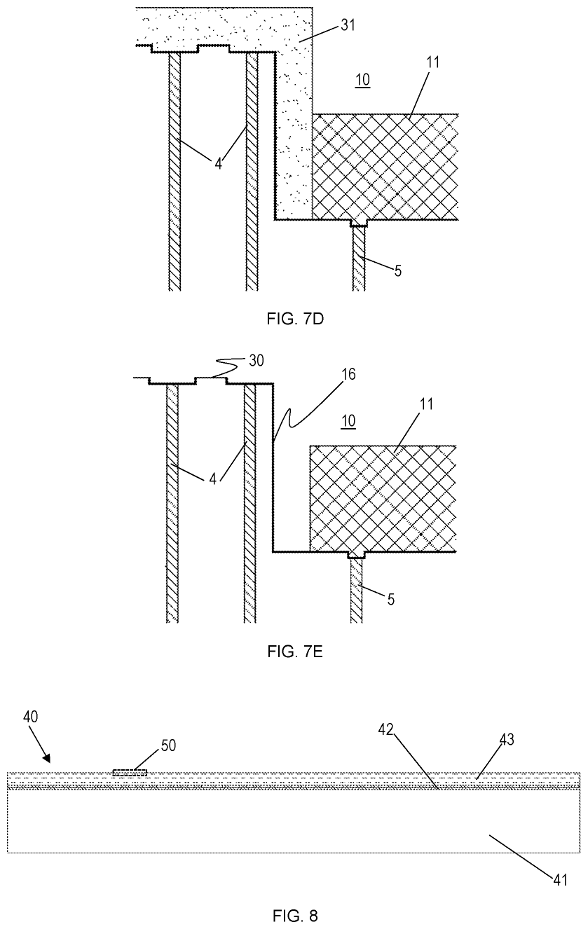

FIG. 7A shows the upper substrate 24 of the assembly shown in FIG. 6 before the deposition of the thin conductive layer 16. The application of the layer 16 is illustrated in FIG. 7B. A patterned mask layer 31 is produced which now covers the sidewall of the large cavity 10 (see FIG. 7C). The device 11 is processed in the large cavity 10 (see FIG. 7D). Then the mask layer 31 is stripped and the bonding surface 30 is planarized, removing the thin layer 16 from the bonding surface (see FIG. 7E). After this, the substrate is bonded to the lower substrate, leading to the result shown in FIG. 6.

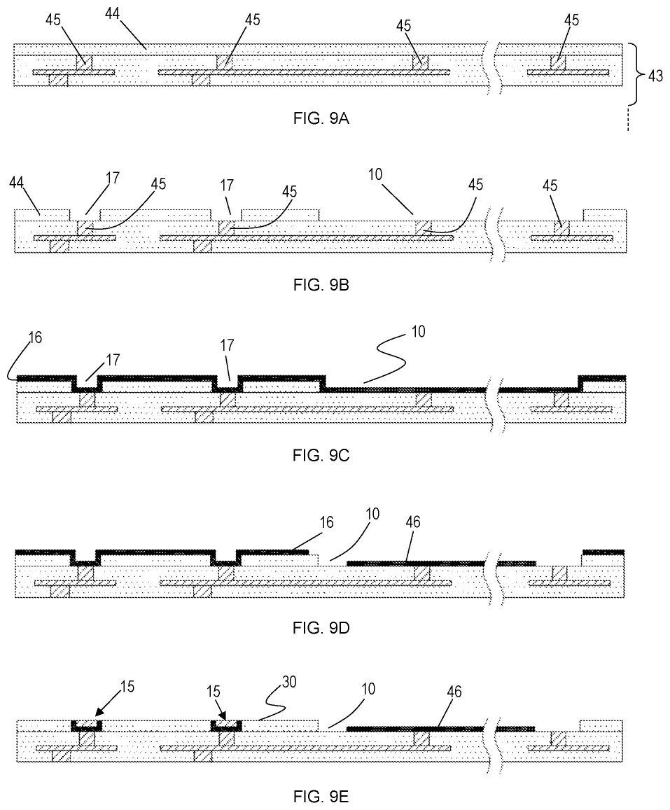

In the above-described embodiments, the large cavities 10 have depths that are significantly higher than the depth of the small cavities 17. This may be required for producing certain types of complete devices or major portions thereof in the large cavities 10. The disclosed technology, however, also includes embodiments in which the large cavities 10 have essentially the same depth as the small cavities 17. An embodiment of this type is illustrated in FIG. 8 and FIGS. 9A to 9E. FIG. 8 represents one substrate 40 that is to be bonded to another substrate by a method according to one embodiment of the disclosed technology. The substrate 40 may be an integrated circuit chip that is either still part of a larger process wafer or that has been separated therefrom by dicing. The chip 40 includes a number of portions that can be implemented using any suitable technology: a silicon substrate 41, a front end of line portion 42 including active devices, and a back end of line portion 43 including multiple interconnect levels. The detail section 50 is shown at an enlarged scale in FIG. 9A. It is shown that the BEOL portion 43 is not fully completed: a dielectric layer 44, for example SiO₂, covers the via connections 45 of the top interconnect level. With reference to FIG. 9B, the small cavities 17 are then produced by lithography and etching, as well as a large cavity 10 having the same depth as the small cavities 17, but having much larger in-plane dimensions, which may be up to a few hundreds of microns, depending on the application. For example, the large cavity 10 could be aimed at containing one plate of a capacitor of a superconducting qubit. The small cavities 17 are aligned to the interconnect vias 45, so that these vias become available for contacting at the bottom of the small cavities 17. Likewise, other interconnect vias 45 become available for contacting at the bottom of the large cavities 10.

As shown in FIG. 9C, the thin conductive layer 16 is formed, as in the previous embodiments, conformally covering the surfaces of both the small and large cavities 17 and 10. Then a mask layer is applied (not shown), and the conductive layer 16 is patterned inside the large cavity 10, for example for forming the capacitor plate 46 (see FIG. 9D). Finally, the small cavities 17 may be filled with a contact metal, after which the substrate is subjected to CMP to arrive at the result shown in FIG. 9E, including the contact pads 15 coplanar with the bonding surface 30. This substrate can then be bonded to another substrate provided with a large, and possibly also deep, cavity, for example including the other plate of the capacitor as well as other parts of the superconducting qubit.

Many practical embodiments of the disclosed technology may require the presence of conductors embedded in the substrates that are to be bonded, and which become available for contacting at the bottom of the small cavities 17 or the large cavities 10. Examples of such conductors are the TSVs 4 and 5 in the embodiments of FIGS. 1A to 1C, 5 and 6, or the interconnect vias 45 in the embodiment of FIGS. 9A to 9E. It is, however, not excluded that one substrate includes only small cavities 17 branching out from a large cavity 10, as in the embodiment of FIG. 6. The small cavities 17 do not require a connection to TSVs or other conductors directly to the bottom of these cavities. These cavities can be connected to matching cavities in the opposite substrate that are coupled to TSVs or other conductors, thereby enabling to contact a device in the large cavity 10.

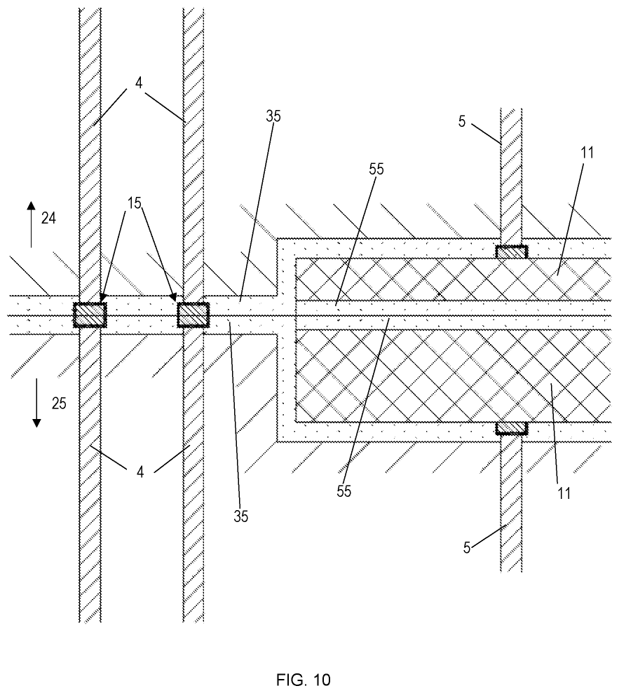

It is not required that an air gap remains above the device 11, as shown in the previous drawings. Certain types of devices may be fully embedded in an oxide for example, as illustrated in FIG. 10, where an oxide layer 55 is formed on top of the device 11 and wherein the layer 55 is coplanar with the oxide bonding layers 35 (as shown in FIGS. 4A to 4C) of the substrates 24 and 25, after the planarization step immediately preceding the bonding step. The surface of the oxide layer 55 thereby becomes an additional part of the bonding surfaces which form the interface between the substrates in the final assembly.

The disclosed technology further relates to an assembly of micro-electronic components obtainable by the methods of the disclosed technology. Such an assembly can be characterized by the fact that it includes at least two stacked components, for example the chip 3 and the interposer 2 illustrated in the embodiment of FIGS. 1A to 1C. The components are bonded along a bonding interface 19, and include matching pluralities of interconnected first cavities 17. In the assembly, the cavities can be said to be “open to the bonding interface 19.” The first cavities 17 of the two components are interconnected at least by layers 16 of a first electrically conductive material lining the sidewalls and bottom of the first cavities 17. At least one component further includes a second cavity 10 open to the bonding interface 19 that has in-plane dimensions that are larger than the in-plane dimensions of the first cavities 17. The second cavity 10 includes a micro-electronic device or a part thereof that is electrically connected, through a layer 16 of the first conductive material present at least on the bottom area of the second cavity 10, to one or more other components of the stacked assembly.

Additional embodiments and alternative forms of the assembly according to the disclosed technology are characterized by the various features and alternatives described in relation to methods of the disclosed technology, such as the presence of the second conductive material 33, the elongate shape and crosswise arrangement of the first cavities 17, and first cavities 17 branching out from a second cavity 10, etc.

While the disclosed technology has been illustrated and described in detail in the drawings and foregoing description, such illustration and description are to be considered illustrative or exemplary and not restrictive. Other variations to the disclosed embodiments can be understood and effected by those skilled in the art in practicing the disclosed technology. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

What is claimed is:

1. A method of producing a stacked assembly of micro-electronic components, the method comprising:
providing a first and a second substrate, each substrate having a planar bonding surface, wherein:
the first substrate and the second substrate both comprise a group of first cavities open to the respective bonding surfaces,
the groups of first cavities are arranged in mutually matching patterns on the first and the second substrate,
at least one of the substrates comprises at least one second cavity open to the bonding surface of the substrate, wherein the second cavity has larger in-plane dimensions than the in-plane dimensions of the first cavities, and
at least one of the substrates comprises electrical conductors embedded in the substrate and available for contacting the conductors at a bottom portion of the first cavities and/or the second cavity;
producing a first and a second layer formed of a first electrically conductive material on the respective bonding surfaces, the layers conformally covering the bonding surfaces and the sidewalls and bottom surfaces of the first cavities and of the second cavity;
patterning the layer formed of the first conductive material in the second cavity and producing a micro-electronic device or a part thereof in the second cavity, wherein the device or part does not extend above the bonding surface of the substrate comprising the second cavity;
by a planarization technique, removing the layers formed of the first electrically conductive material from the bonding surfaces while keeping the layers at least on the bottom and sidewalls of the first cavities; and
bonding and interconnecting the substrates, to thereby obtain the stacked assembly of components, wherein at least the sidewalls of the first cavities of the first substrate overlap corresponding sidewalls of the first cavities of the second substrate so that an electrical connection is established between the respective sidewalls, and wherein the device or device part in the second cavity is electrically connected to one or more other components of the stack.

2. The method according to claim 1, further comprising the following steps applied to the first substrate and the second substrate:
prior to applying the planarization technique, depositing a second electrically conductive material in the first cavities and on the bonding surface in between the first cavities; and
by applying the planarization technique, removing both the second and first conductive materials from the bonding surface, before performing the bonding step.

3. The method according to claim 1, wherein on at least one of the substrates, the second cavity and a plurality of the first cavities are together forming a common cavity, the plurality of the first cavities branching out from one or more sidewalls of the second cavity, and wherein the layer of the first conductive material is maintained on the one or more sidewalls of the second cavity so that the layer forms an electrical connection between the plurality of the first cavities and the second cavity.

4. The method according to claim 1, wherein the electrical connection between the matching first cavities of the two substrates is established only by the layers of the first conductive material on the sidewalls and the bottom of the first cavities.

5. The method according to claim 1, wherein the first cavities have an elongate shape, and wherein the first cavities of the first substrate overlap the first cavities of the second substrate in a crosswise fashion.

6. The method according to claim 1, wherein at least one of the substrates comprises a plurality of conductors embedded in the substrate and arranged so that a number of the conductors are available for contacting at the bottom of the first cavities and/or at the bottom of the second cavity.

7. The method according to claim 6, wherein at least some of the number of conductors are through substrate via (TSV) connections.

8. The method according to claim 6, wherein at least some of the number of conductors are interconnect vias which are part of a back end of line type interconnect structure.

9. The method according to claim 1, wherein the depth of the second cavity is considerably larger than the depth of the first cavities.

10. The method according to claim 1, wherein the depth of the second cavity is the same as the depth of the first cavities.

11. The method according to claim 1, wherein the devices or parts thereof comprise superconducting qubits or parts thereof.

12. The method according to claim 11, wherein the first substrate comprises a number of the second cavities, each of the number comprising multiple elements of a superconducting qubit including one plate of a capacitor, and wherein the second substrate comprises an equal number of the second cavities, each comprising another capacitor plate that is capacitively coupled to the plates in the first substrate after the bonding step.

13. A stacked assembly of micro-electronic components, at least two of the components being bonded along a bonding interface, and comprising matching pluralities of interconnected first cavities open to the bonding interface, wherein the first cavities of the two components are interconnected at least by layers of a first electrically conductive material lining the sidewalls and bottom of the first cavities, and wherein at least one component further comprises a second cavity open to the bonding interface that has in-plane dimensions which are larger than the in-plane dimensions of the first cavities, and wherein the second cavity comprises a micro-electronic device or a part thereof that is electrically connected to one or more other components of the stacked assembly.

14. The assembly according to claim 13, wherein the devices or parts thereof comprise superconducting qubits or parts thereof.
